(19) United States
(12) Patent Application Publication
(10) Pub. No.: US 2024/0321665 A1
(43) Pub. Date: Sep. 26, 2024

(54) SEMICONDUCTOR DEVICE AND POWER CONVERSION DEVICE

(71) Applicants: Kabushiki Kaisha Toshiba, Tokyo (JP); Toshiba Electronic Devices & Storage Corporation, Tokyo (JP)

(72) Inventor: Fumiyoshi KAWASHIRO, Tokyo (JP)

(21) Appl. No.: 18/243,627

(22) Filed: Sep. 7, 2023

(30) Foreign Application Priority Data
Mar. 23, 2023 (JP) 2023-047086

(51) Int. Cl. H01L 23/31; H01L 23/00; H01L 23/29; H01L 25/16

(52) U.S. Cl. CPC H01L 23/3135; H01L 23/293; H01L 24/29; H01L 24/32; H01L 25/165; H01L 23/49537; H01L 23/49562; H01L 23/49579; H01L 2224/29111; H01L 2224/29116; H01L 2224/29139; H01L 2224/29144; H01L 2224/29147; H01L 2224/32245; H01L 2924/13091

(57) ABSTRACT

According to one embodiment, a semiconductor device includes a semiconductor chip, drain, source and gate electrodes, mold layers and first and second coating films. The semiconductor chip has a drain region on a first surface, and source and gate regions on a second surface facing the first surface. The drain electrode is provided on the drain region. The source electrode is provided on the source region. The gate electrode is provided on the gate region. The mold layers are provided on side surfaces of the semiconductor chip, the source and gate electrodes. The first coating films are provided on a lower surface and side surfaces of the drain electrode, an upper surface of the source electrode, and an upper surface of the gate electrode. The second coating films are provided on an upper surface and side surfaces of the mold layers.

### CROSS-REFERENCE TO RELATED APPLICATIONS

This application is based upon and claims the benefit of priority from Japanese Patent Application No. 2023-047086, filed Mar. 23, 2023, the entire contents of which are incorporated herein by reference.

### FIELD

Embodiments described herein relate generally to a semiconductor device and a power conversion device.

### BACKGROUND

A semiconductor device, such as a power MOSFET mounted on a printed board, is known as a switching element used as a power conversion device (for example, a DC-DC converter).

### BRIEF DESCRIPTION OF THE DRAWINGS

FIG. 1 is a perspective view of a semiconductor device according to a first embodiment.

FIG. 2 is a top view of the semiconductor device according to the first embodiment.

FIG. 3 is a cross-sectional view of the semiconductor device taken along line III-III shown in FIG. 2.

FIG. 4 is a detailed cross-sectional view of a semiconductor chip and a conductive layer according to the first embodiment.

FIG. 5 is a top view of a semiconductor device according to a second embodiment.

FIG. 6 is a cross-sectional view of the semiconductor device taken along line VI-VI shown in FIG. 5.

FIG. 7 is a detailed cross-sectional view of a semiconductor chip and a conductive layer according to the second embodiment.

FIG. 8 is a circuit diagram of a power conversion device according to a third embodiment.

FIG. 9 is a top view of the power conversion device according to the third embodiment.

FIG. 10 is a cross-sectional view of the power conversion device taken along line X-X shown in FIG. 9.

FIG. 11 is a top view of a power conversion device according to a fourth embodiment.

FIG. 12 is a cross-sectional view of the power conversion device taken along line XII-XII shown in FIG. 11.

FIG. 13 is a cross-sectional view of a power conversion device according to a fifth embodiment.

### DETAILED DESCRIPTION

In general, according to one embodiment, a semiconductor device includes a semiconductor chip having a drain region on a first surface, and a source region and a gate region on a second surface facing the first surface; a drain electrode provided on the drain region; a source electrode provided on the source region; a gate electrode provided on the gate region; mold layers provided on side surfaces of the semiconductor chip, the source electrode, and the gate electrode; first coating films provided on a lower surface and side surfaces of the drain electrode, an upper surface of the source electrode, and an upper surface of the gate electrode; and second coating films provided on an upper surface and side surfaces of the mold layers.

Hereinafter, embodiments will be described with reference to the drawings. In the descriptions below, constituent elements having the same functions and configurations will be denoted by the same reference symbols. Each of the following embodiments is shown to present an example of a device and a method for carrying out the technical concept of the embodiment, and it is to be understood that the materials, the shapes, the structures, the arrangements, and the like of the constituent components are not limited to those shown below. In the drawings that will be referred to hereinafter, structural elements, such as insulating layers, coating films, interconnects, and contacts, are omitted for better visibility.

### 1. First Embodiment

A semiconductor device according to a first embodiment is described. A semiconductor device includes a MOS field-effect transistor (MOSFET) as a switching element, for example. The MOSFET of the first embodiment has a drain on a first surface (which may also be referred to as a “lower surface” or a “rare surface”), and a source and a gate on a second surface (which may also be referred to as an “upper surface” or a “front surface”) facing the first surface. The MOSFET is used in a power conversion device, such as a DC-DC converter or an inverter. An example in which a MOSFET is applied to a power conversion device will be described in the third embodiment and thereafter.

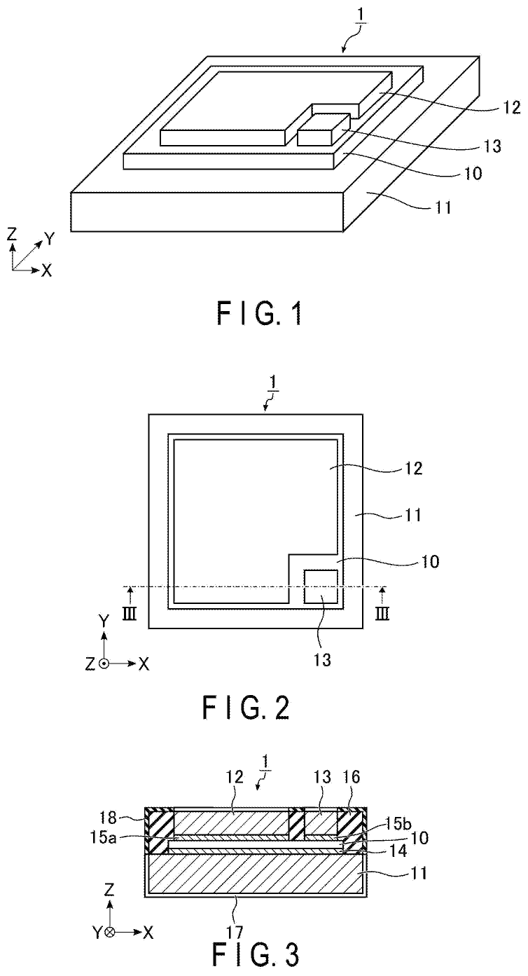

FIG. 1 is a perspective view of the semiconductor device of the first embodiment. FIG. 2 is a top view of the semiconductor device of the first embodiment, and FIG. 3 is a cross-sectional view of the semiconductor device taken along line III-III shown in FIG. 2. In these drawings and thereafter, two directions parallel to a first surface of the semiconductor device and orthogonal to each other are defined as an X direction and a Y direction, and the direction orthogonal to a surface including the X and Y directions (X-Y plane) is defined as a Z direction. In FIGS. 1 and 2, coating films and mold layers, etc. are omitted.

As shown in FIGS. 1, 2, and 3, the semiconductor device 1 includes a semiconductor chip 10, a drain electrode plate (or drain electrode, drain electrode layer) 11, a source electrode plate (or source electrode, source electrode layer) 12, a gate electrode plate (or gate electrode, gate electrode layer) 13, conductive layers 14, 15a, and 15b, mold layers 16, and coating films 17 and 18.

The semiconductor chip 10 includes a MOSFET, for example. The semiconductor chip 10 has a first surface orthogonal to the z direction and a second surface facing the first surface. The first surface is the lower surface of the semiconductor chip 10 shown in FIG. 3, and the second surface is the upper surface of the semiconductor chip 10 shown in FIG. 3. The semiconductor chip 10 has a drain region on the first surface, and a source region and a gate region on the second surface.

The semiconductor chip 10 is provided between the drain electrode plate 11 and the source electrode and gate electrode plates 12 and 13. In other words, the drain electrode plate 11 is provided below the drain region of the semiconductor chip 10. The source electrode plate 12 is provided on the source region of the semiconductor chip 10. Furthermore, the gate electrode plate 13 is provided on the gate region of the semiconductor chip 10.

The drain electrode plate 11 has a thin-plate shape, and includes a lead frame, for example. The thickness of the drain electrode plate 11 is, for example, 50 μm or greater, or 150 μm or greater and 300 μm or less. Similar to the drain electrode plate 11, the source electrode plate 12 has a thin-plate shape, and includes a lead frame, for example. The thickness of the source electrode plate 12 is, for example, 50 μm or greater, or 150 μm or greater and 300 μm or less. The gate electrode plate 13 has a thin-plate shape, and includes a lead frame, for example. The thickness of the gate electrode plate 13 is, for example, 50 μm or greater, or 150 μm or greater and 300 μm or less. The drain electrode plate 11, the source electrode plate 12, and the gate electrode plate 13 contain Cu, for example.

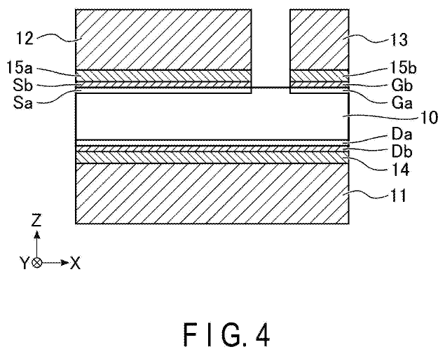

Hereinafter, the structures of the source region, the drain region, and the gate region of the semiconductor chip 10, and the conductive layers 14, 15a, and 15b are described. FIG. 4 is a detailed cross-sectional view of the semiconductor chip 10 and the conductive layers 14, 15a, and 15b.

The conductive layer 14 is provided between the drain region Da of the semiconductor chip 10 and the drain electrode plate 11. The electrode layer Db is arranged below the drain region Da. The drain electrode plate 11 is arranged below the electrode layer Db, with the conductive layer 14 being interposed therebetween.

The drain region Da is, for example, an n-type semiconductor layer, namely an n-type diffusion layer. The electrode layer Db includes at least one of, for example, a stacked structure of Al, Ni, and Au, a stacked structure of Al, Ni, Pd, and Au, a stacked structure of Al and Cu, or a single-layer structure of Cu. The conductive layer 14 contains a conductive metal material or a sintering material (for example, a welding material or a sintering material made of Ag). Specifically, the conductive layer 14 contains at least one of Ag, Cu, CuSn, AgSn, AuSn, or PbSn, for example.

The conductive layer 14 is heated while it is being pressed or not pressed, so that the electrode layer Db on the semiconductor chip 10 and the drain electrode plate 11 are bonded or sintered. The drain electrode plate 11 is electrically coupled to the drain of the semiconductor chip 10 (namely, the electrode layer Db and the drain region Da), via the conductive layer 14.

The conductive layer 15a is provided between the source region Sa of the semiconductor chip 10 and the source electrode plate 12. An electrode layer Sb is arranged on the source region Sa. The source electrode plate 12 is arranged on the electrode layer Sb, with the conductive layer 15a being interposed therebetween.

The source region Sa is, for example, an n-type semiconductor layer, namely an n-type diffusion layer. The electrode layer Sb includes at least one of, for example, a stacked structure of Al, Ni, and Au, a stacked structure of Al, Ni, Pd, and Au, a stacked structure of Al and Cu, or a single-layer structure of Cu. The conductive layer 15a contains a conductive metal material or a sintering material (for example, a soldering material or a sintering material made of Ag). Specifically, the conductive layer 15a contains at least one of Ag, Cu, CuSn, AgSn, AuSn, or PbSn, for example.

The conductive layer 15a is heated while it is being pressed or not pressed, so that the electrode layer Sb on the semiconductor chip 10 and the source electrode plate 12 are bonded or sintered. The source electrode plate 12 is electrically coupled to the source of the semiconductor chip 10 (namely the electrode layer Sb and the source region Sa) via the conductive layer 15a.

The conductive layer 15b is provided between the gate region Sa of the semiconductor chip 10 and the gate electrode plate 13. An electrode layer Gb is arranged on the gate region Ga. The gate electrode plate 13 is arranged on the electrode layer Gb, with the conductive layer 15b being interposed therebetween.

The gate region Ga is, for example, an n-type semiconductor layer, namely an n-type diffusion layer. The electrode layer Gb includes at least one of, for example, a stacked structure of Al, Ni, and Au, a stacked structure of Al, Ni, Pd, and Au, a stacked structure of Al and Cu, or a single-layer structure of Cu. The conductive layer 15b contains a conductive metal material or a sintering material (for example, a soldering material or a sintering material made of Ag). Specifically, the conductive layer 15b contains at least one of Ag, Cu, CuSn, AgSn, AuSn, or PbSn, for example.

The conductive layer 15b is heated while it is being pressed or not pressed, so that the electrode layer Gb on the semiconductor chip 10 and the gate electrode plate 13 are bonded or sintered. The gate electrode plate 13 is electrically coupled to the gate (namely the electrode layer Gb and the gate region Ga) of the semiconductor chip 10 via the conductive layer 15b.

Explanation will continue, returning to FIG. 3. A mold layer 16 is provided on the drain electrode plate 11 and the side surfaces of the source electrode plate 12 and the semiconductor chip 10. A mold layer 16 is provided on the drain electrode plate 11 and the side surfaces of the gate electrode plate 13 and the semiconductor chip 10. A mold layer 16 is provided also on the semiconductor chip 10 and between the source electrode plate 12 and the gate electrode plate 13. These mold layers 16 stably maintain the insulation and arrangements between the semiconductor chip 10, the drain electrode plate 11, the source electrode plate 12, and the gate electrode plate 13 in the semiconductor device 1.

A coating film 17 is provided to cover the surfaces of the drain electrode plate 11, the source electrode plate 12, and the gate electrode plate 13. The coating film 17 covers the entire or part of the surfaces of the drain electrode plate 11, the source electrode plate 12, and the gate electrode plate 13. Specifically, the coating film 17 is provided on the lower surface and the side surfaces of the drain electrode plate 11, the upper surface of the source electrode plate 12, and the upper surface of the gate electrode plate 13. If a contact material (or interconnect) is provided to be coupled to each of the drain electrode plate 11, the source electrode plate 12, and the gate electrode plate 13, part of the coating film 17 covering these elements is removed. It is thus possible to electrically couple the contact material to each of the drain electrode plate 11, the source electrode plate 12, and the gate electrode plate 13.

If the semiconductor device 1 is mounted on a substrate, for example a printed wiring board (or a printed board), the coating film 17 improves adherence between the drain electrode plate 11, the source electrode plate 12, and the gate electrode plate 13 and the layers provided around these electrode plates.

The coating film 17 may be a metal film, for example a film containing Sn or Ni and Au or a film containing Ni, Pd, and Au, and may include an insulating film, for example a rust inhibitor such as benzotriazole (BTA).

A coating film 18 is provided to cover the surface of the mold layer 16. The coating film 18 coats the entire or part of the surfaces of the mold layers 16. Specifically, the coating film 18 is provided on the upper and side surfaces of the mold layers 16. If the semiconductor device 1 is mounted on a board, for example a printed wiring board, etc., the coating film 18 improves adherence between the mold layers 16 and the layers provided around these mold layers 16. The coating film 18 includes an insulating film, for example.

The thickness of the semiconductor device 1 shown in FIG. 3 with respect to the Z direction is, for example, 500 μm or less, or 400 μm or less. In other words, the thickness of a stacked structure in which the drain electrode plate 11, the semiconductor chip 10, and the source electrode plate 12 are arranged in this order is, for example, 500 μm or less, or 400 μm or less.

Main advantageous effects of the first embodiment are described below.

In the foregoing first embodiment, the drain electrode plate 11 coupled to the drain of the semiconductor chip 10 is provided on the first surface of the semiconductor device 1, and the source electrode plate 12 and the gate electrode plate 13 coupled respectively to the source and the gate of the semiconductor chip 10 are provided on the second surface facing the first surface of the semiconductor device 1. According to the first embodiment, since the electrode plates are provided on the first surface and the second surface of the semiconductor device 1, the semiconductor device 1 can be easily embedded in a printed board having multilayered wiring (for example, a double-sided board).

According to the structure of the first embodiment, it is possible to improve heat dissipation of the semiconductor device 1 by providing electrode plates, for example thin-plate (or sheet-shaped) electrode plates made of Cu, on the first and second surfaces of the semiconductor device 1. For example, heat dissipation of the semiconductor device 1 can be remarkably improved by making the thickness of at least one of the drain electrode plate 11, the source electrode plate 12, or the gate electrode plate 13 be 50 μm or greater (or 150 μm or greater and 300 μm or less).

Furthermore, it is easy to form an interconnect layer using Cu in the printed board on which the semiconductor device 1 is mounted.

In the first embodiment, the example is described in which the semiconductor device 1 includes a MOSFET; however, the semiconductor device 1 may include an insulated gate bipolar transistor (IGBT) or a junction field effect transistor (JFET). If the semiconductor device 1 includes an IGBT, the source electrode plate 12 corresponds to an emitter electrode and the drain electrode plate 11 corresponds to a collector electrode.

### 2. Second Embodiment

A semiconductor device according to the second embodiment is described. A semiconductor device includes a MOSFET as a switching element, for example. The MOSFET of the second embodiment has a source and a gate on a first surface (may be alternatively referred to as a “lower surface” or a “rare surface”), and a drain on a second surface (may be alternatively referred to as an “upper surface” or a “front surface”) facing the first surface. The MOSFET is used in a power conversion device, such as a DC-DC converter or an inverter. Herein, the description of the perspective view described in the first embodiment is omitted. The explanation of the second embodiment will focus mainly on the points that differ from the first embodiment.

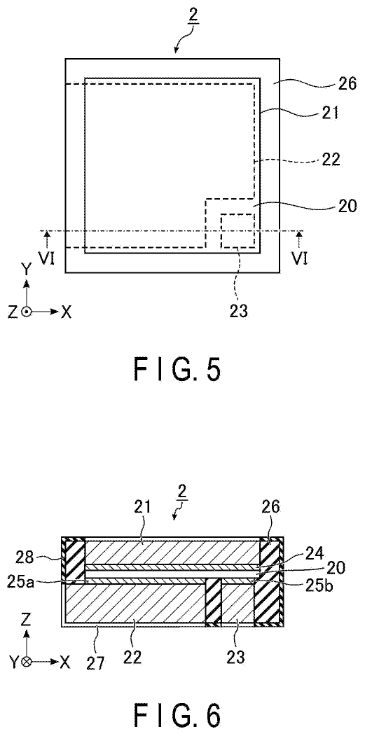

FIG. 5 is a top view of the semiconductor device according to the second embodiment. FIG. 6 is a cross-sectional view of the semiconductor device taken along line VI-VI shown in FIG. 5. In FIG. 5, coating films and mold layers, etc. are omitted.

As shown in FIGS. 5 and 6, the semiconductor device 2 includes a semiconductor chip 20, a drain electrode plate (or drain electrode, drain electrode layer) 21, a source electrode plate (or source electrode, source electrode layer) 22, a gate electrode plate (or gate electrode, gate electrode layer) 23, conductive layers 24, 25a, and 25b, mold layers 26, and coating films 27 and 28.

The semiconductor chip 20 includes a MOSFET, for example. The semiconductor chip 20 has a first surface orthogonal to the Z direction and a second surface facing the first surface. The first surface is a lower surface of the semiconductor chip 20 shown in FIG. 6, and the second surface is an upper surface of the semiconductor chip 20 shown in FIG. 6. The semiconductor chip 20 has a source region and a gate region on the first surface and a drain region on the second surface.

The semiconductor chip 20 is provided between the source electrode and gate electrode plates 22 and 23 and the drain electrode plate 21. In other words, the source electrode plate 22 is provided below the source region of the semiconductor chip 20. The gate electrode plate 23 is provided below the gate region of the semiconductor chip 20. Furthermore, the drain electrode plate 21 is provided on the drain region of the semiconductor chip 20.

The source electrode plate 22 has a thin-plate shape, and includes a lead frame, for example. The thickness of the source electrode plate 22 is, for example, 50 μm or greater, or 150 μm or greater and 300 μm or less. Similar to the source electrode plate 22, the gate electrode plate 23 has a thin-plate shape, and includes a lead frame, for example. The thickness of the gate electrode plate 23 is, for example, 50 μm or greater, or 150 μm or greater and 300 μm or less. The drain electrode plate 21 has a thin-plate shape, and includes a lead frame, for example. The thickness of the drain electrode plate 21 is, for example, 50 μm or greater, or 150 μm or greater and 300 μm or less. The source electrode plate 22, the gate electrode plate 23, and the drain electrode plate 21 contain Cu, for example.

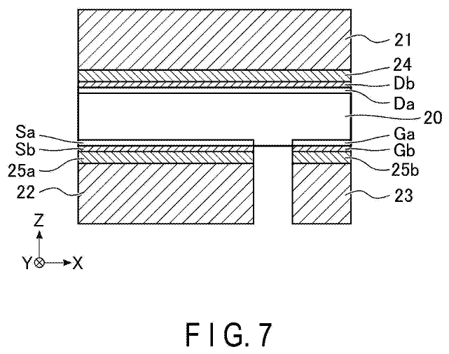

Hereinafter, the structures of the source region, the drain region, and the gate region of the semiconductor chip 20, and the conductive layers 24, 25a, and 25b are described. FIG. 7 is a detailed cross-sectional view of the semiconductor chip 20 and the conductive layers 24, 25a, and 25b.

The conductive layer 24 is provided between the drain region Da of the semiconductor chip 20 and the drain electrode plate 21. The electrode layer Db is arranged on the drain region Da. The drain electrode plate 21 is arranged on the electrode layer Db, with the conductive layer 24 being interposed therebetween.

The drain region Da is, for example, an n-type semiconductor layer, namely an n-type diffusion layer. The electrode layer Db includes at least one of, for example, a stacked structure of Al, Ni, and Au, a stacked structure of Al, Ni, Pd, and Au, a stacked structure of Al and Cu, or a single-layer structure of Cu. The conductive layer 24 contains a conductive metal material or a sintering material (for example, a soldering material or a sintering material made of Ag). Specifically, the conductive layer 24 contains at least one of Ag, Cu, CuSn, AgSn, AuSn, or PbSn, for example.

The conductive layer 24 is heated while it is being pressed or not pressed, so that the electrode layer Db on the semiconductor chip 20 and the drain electrode plate 21 are bonded or sintered. The drain electrode plate 21 is electrically coupled to the drain of the semiconductor chip 20 (namely, the electrode layer Db and the drain region Da), via the conductive layer 24.

The conductive layer 25a is provided between the source region Sa of the semiconductor chip 20 and the source electrode plate 22. The electrode layer Sb is arranged below the source region Sa. The source electrode plate 22 is arranged below the electrode layer Sb, with the conductive layer 25a being interposed therebetween.

The source region Sa is, for example, an n-type semiconductor layer, namely an n-type diffusion layer. The electrode layer Sb includes at least one of, for example, a stacked structure of Al, Ni, and Au, a stacked structure of Al, Ni, Pd, and Au, a stacked structure of Al and Cu, or a single-layer structure of Cu. The conductive layer 25a contains a conductive metal material or a sintering material (for example, a soldering material or a sintering material made of Ag). Specifically, the conductive layer 25a contains at least one of Ag, Cu, CuSn, AgSn, AuSn, or PbSn, for example.

The conductive layer 25a is heated while it is being pressed or not pressed, so that the electrode layer Sb on the semiconductor chip 20 and the source electrode plate 22 are bonded or sintered. The source electrode plate 22 is electrically coupled to the source of the semiconductor chip 20 (namely the electrode layer Sb and the source region Sa) via the conductive layer 25a.

The conductive layer 25b is provided between the gate region Ga of the semiconductor chip 20 and the gate electrode plate 23. The electrode layer Gb is arranged below the gate region Ga. The gate electrode plate 23 is arranged below the electrode layer Gb, with the conductive layer 25b being interposed therebetween.

The gate region Ga is, for example, an n-type semiconductor layer, namely an n-type diffusion layer. The electrode layer Gb includes at least one of, for example, a stacked structure of Al, Ni, and Au, a stacked structure of Al, Ni, Pd, and Au, a stacked structure of Al and Cu, or a single-layer structure of Cu. The conductive layer 25b contains a conductive metal material or a sintering material (for example, a soldering material or a sintering material made of Ag). Specifically, the conductive layer 25b contains at least one of Ag, Cu, CuSn, AgSn, AuSn, or PbSn, for example.

The conductive layer 25b is heated while it is being pressed or not pressed, so that the electrode layer Gb on the semiconductor chip 20 and the gate electrode plate 23 are bonded or sintered. The gate electrode plate 23 is electrically coupled to the gate (namely the electrode layer Gb and the gate region Ga) of the semiconductor chip 20 via the conductive layer 25b.

Explanation will continue, returning to FIG. 6. Mold layers 26 are provided on the source electrode plate 22 and the side surfaces of the drain electrode plate 21 and the semiconductor chip 20. Mold layers 26 are provided on the side surfaces of the gate electrode plate 23, the semiconductor chip 20, and the drain electrode plate 21. These mold layers 16 stably maintain the insulation and arrangements between the semiconductor chip 20, the drain electrode plate 21, the source electrode plate 22, and the gate electrode plate 23 in the semiconductor device 1.

A coating film 27 is provided to cover the surfaces of the drain electrode plate 21, the source electrode plate 22, and the gate electrode plate 23. The coating film 27 covers the entire or part of the surfaces of the drain electrode plate 21, the source electrode plate 22, and the gate electrode plate 23. If a contact material (or interconnect) is provided to be coupled to each of the drain electrode plate 21, the source electrode plate 22, and the gate electrode plate 23, part of the coating film 27 covering these elements is removed. It is thus possible to electrically couple the contact material to each of the drain electrode plate 21, the source electrode plate 22, and the gate electrode plate 23.

If the semiconductor device 1 is mounted on a substrate, for example a printed wiring board, the coating film 27 improves adherence between the drain electrode plate 21, the source electrode plate 22, and the gate electrode plate 23 and the layers provided around these electrode plates.

The coating film 27 may be a metal film, for example Sn or a stacked film of Ni and Au or a stacked film of Ni, Pd, and Au, and may include an insulating film, for example a rust inhibitor such as benzotriazole (BTA).

A coating film 28 is provided to cover the surface of the mold layers 26. The coating film 28 coats the entire or part of the surface of the mold layers 26. If the semiconductor device 1 is mounted on a board, for example a printed wiring board, etc., the coating film 28 improves adherence between the mold layers 26 and the layers provided around these mold layers 26. The coating film 28 includes an insulating film, for example.

The thickness of the semiconductor device 1 shown in FIG. 6 with respect to the Z direction is, for example, 500 μm or less or 400 μm or less.

Hereinafter, major advantageous effects of the second embodiment are explained.

In the foregoing second embodiment, the source electrode plate 22 and the gate electrode plate 23 coupled respectively to the source and the gate of the semiconductor chip 20 are provided on the first surface of the semiconductor device 2, and the drain electrode plate 21 coupled to the drain of the semiconductor chip 20 is provided on the second surface facing the first surface of the semiconductor device 2. According to the second embodiment, since the electrode plates are provided on the first surface and the second surface of the semiconductor device 2, the semiconductor device 2 can be easily embedded in a printed board having multilayered wiring (for example, double-sided board).

According to the structure of the second embodiment, it is possible to improve heat dissipation of the semiconductor device 2 by providing electrode plates, for example thin-plate (or sheet-shaped) electrode plates made of Cu, on the first and second surfaces of the semiconductor device 2. For example, heat dissipation of the semiconductor device 2 can be remarkably improved by making the thickness of at least one of the drain electrode plate 21, the source electrode plate 22, or the gate electrode plate 23 be 50 μm or greater (or 150 μm or greater and 300 μm or less).

Furthermore, it is easy to form an interconnect layer using Cu in the printed board on which the semiconductor device 2 is mounted.

In the second embodiment, the example is described in which the semiconductor device 2 includes a MOSFET; however, the semiconductor device 2 may include an insulated gate bipolar transistor (IGBT) or a junction field effect transistor (JFET).

### 3. Third Embodiment

A power conversion device according to the third embodiment is described. In the third embodiment, a power conversion device comprising a plurality of semiconductor devices of the first embodiment is described. Herein, a DC-DC converter is described as an example of a power conversion device. The explanation of the third embodiment will focus mainly on the points that differ from the first embodiment.

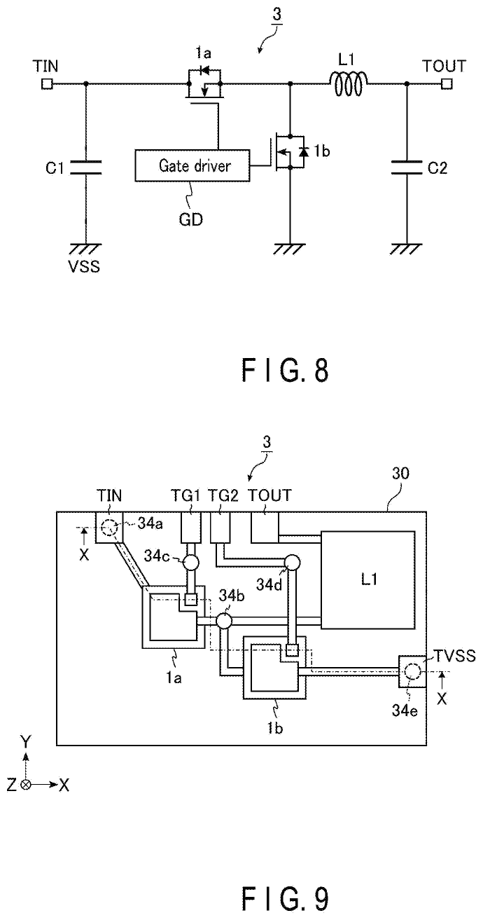

First, the circuit configuration of the power conversion device according to the third embodiment is described. FIG. 8 is a circuit diagram of a power conversion device according to the third embodiment.

The power conversion device 3 includes a plurality of semiconductor devices 1a and 1b, an inductor L1, and capacitors C1 and C2. Each of the semiconductor device 1a and 1b corresponds to the semiconductor device 1 of the first embodiment and includes a MOSFET.

Hereinafter, a coupling relationship of circuit elements constituting the power conversion device 3 is explained. The input terminal TIN is coupled to the drain of the semiconductor device 1a. The input terminal TIN is also coupled to a voltage VSS node via the capacitor C1. The ground voltage VSS is applied to the voltage VSS node.

The source of the semiconductor device 1a is coupled to the drain of the semiconductor device 1b and the first end of the inductor L1. The source of the semiconductor device 1b is coupled to the voltage VSS node. A gate driver GD is coupled to each of the gates of the semiconductor devices 1a and 1b.

The second end of the inductor L1 is coupled to the output terminal TOUT. The second end of the inductor L1 is also coupled to the voltage VSS node via the capacitor C2.

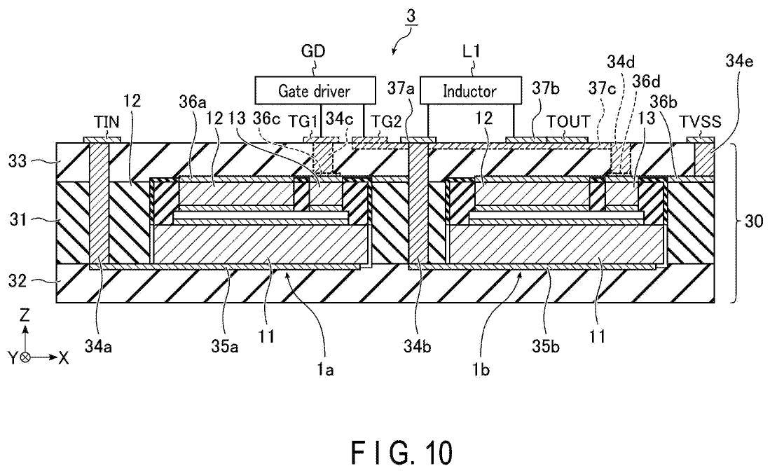

Next, a planar layout and a cross-sectional structure of the power conversion device 3 of the third embodiment is described. FIG. 9 is a top view of the power conversion device of the third embodiment. FIG. 10 is a cross-sectional view of the power conversion device taken along line X-X shown in FIG. 9. The cross-sectional view shown in FIG. 10 shows not only the structure seen on the cross section but also the structures that can be seen through the cross section, such as through holes and interconnect layers. The power conversion device 3 includes a structure in which the semiconductor devices 1a and 1b are embedded in the printed wiring board 30. The printed wiring board 30 is a multilayered wiring board (for example, a double-sided wiring board) including a plurality of interconnect layers, a plurality of insulating plates (or insulating layers), and a core member.

As shown in FIGS. 9 and 10, the power conversion device 3 includes a plurality of semiconductor devices 1a and 1b, core members (or insulating members) 31, insulating plates (or insulating layers) 32 and 33, through holes 34a, 34b, 34c, 34d, and 34e, interconnect layers 35a, 35b, 36a, 36b, 36c, 36d, 37a, 37b, and 37c, an input terminal TIN, an output terminal TOUT, gate terminals TG1 and TG2, a ground terminal TVSS (namely a voltage VSS node), an inductor L1, and capacitors C1 and C2. The capacitors C1 and C2 are provided at positions not shown in the drawings. Each of the insulating plates 32 and 33 has, for example, a shape of a sheet and is made of an insulating material obtained by impregnating a thermoset resin in carbon fibers.

As shown in FIG. 10, the semiconductor device 1a is provided between the insulating plate 32 and the insulating plate 33 with respect to the Z direction and between the core members 31 with respect to the X direction and the Y direction. Similarly, the semiconductor device 1b is provided between the insulating plate 32 and the insulating plate 33 with respect to the Z direction, and provided between the core members 31 with respect to the X direction and the Y direction.

In other words, the semiconductor devices 1a and 1b are provided separately from each other on the insulating plate 32. The insulating plate 33 is provided on the semiconductor devices 1a and 1b. The core members 31 are provided on the side surfaces of the semiconductor devices 1a and 1b. In other words, the core member 31 is provided so as to cover the side surfaces of the semiconductor device 1a. Similarly, the core member 31 is provided so as to cover the side surfaces of the semiconductor device 1b.

The input terminal TIN, the output terminal TOUT, the gate terminals TG1 and TG2, and the ground terminal TVSS are provided on the insulating plate 33.

The through holes 34a and 34b are provided in the insulating plate 33 and the core member 31. Each of the through holes 34a and 34b extends in the Z direction in the insulating plate 33 and the core members 31. The through holes 34c, 34d, and 34e are provided in the insulating plate 33. The through holes 34c, 34d, and 34e extend in the Z direction in the insulating plate 33.

An interconnect layer 35a is provided between the drain electrode plate 11 of the semiconductor device 1a and the insulating plate 32. The interconnect layer 35a diagonally extends with respect to the X direction and the Y direction. An interconnect layer 36a is provided between the source electrode plate 12 of the semiconductor device 1a and the insulating plate 33. The interconnect layer 36a extends in the X direction.

An interconnect layer 35b is provided between the drain electrode plate 11 of the semiconductor device 1b and the insulating plate 32. The interconnect layer 35b extends in the X direction and the Y direction. An interconnect layer 36b is provided between the source electrode plate 12 of the semiconductor device 1b and the insulating plate 33. The interconnect layer 36b extends in the X direction. The interconnect layers 37a, 37b, and 37c are further provided on the insulating plate 33. The interconnect layers 37a, 37b, and 37c extend in the X direction or the Y direction.

The input terminal TIN is coupled to the through hole 34a. The through hole 34a is coupled to the interconnect layer 35a. The interconnect layer 35a is further coupled to the drain electrode plate 11 of the semiconductor device 1a.

The source electrode plate 12 of the semiconductor device 1a is coupled to the interconnect layer 36a. The interconnect layer 36a is coupled to the through hole 34b. The through hole 34b is coupled to the interconnect layer 35b. The interconnect layer 35b is further coupled to the drain electrode plate 11 of the semiconductor device 1b. The through hole 34b is coupled to the first end of the inductor L1 via the interconnect layer 37a. The second end of the inductor L1 is coupled to the output terminal TOUT via the interconnect layer 37b. The inductor L1 is mounted on the surface of the printed wiring board 30, for example.

The source electrode plate 12 of the semiconductor device 1b is coupled to the interconnect layer 36b. The interconnect layer 36b is coupled to the through hole 34e. The through hole 34e is coupled to the terminal TVSS.

The gate electrode plate 13 of the semiconductor device 1a is coupled to the through hole 34c via the interconnect layer 36c. The through hole 34c is coupled to the gate terminal TG1. The gate electrode plate 13 of the semiconductor device 1b is coupled to the through hole 34d via the interconnect layer 36d. The through hole 34d is coupled to the gate terminal TG2 via the interconnect layer 37c. A gate driver GD is coupled to the gate terminals TG1 and TG2.

Hereinafter, major advantageous effects of the third embodiment are explained.

According to the structure of the foregoing third embodiment, it is possible to easily embed the semiconductor devices 1a and 1b in the printed board, and to form a power conversion device, such as a DC-DC converter, with a small area. The other advantages are the same as those of the first embodiment.

### 4. Fourth Embodiment

A power conversion device according to the fourth embodiment is described. In the fourth embodiment, a power conversion device comprising a plurality of semiconductor devices of the first and second embodiments is described. Herein, similarly to the third embodiment, a DC-DC converter is described as an example. The explanation of the fourth embodiment will focus mainly on the points that differ from the first through third embodiments.

The power conversion device of the fourth embodiment has a semiconductor device 2a instead of the semiconductor device 1b in the third embodiment. The other configuration is similar to that of the third embodiment shown in FIG. 8.

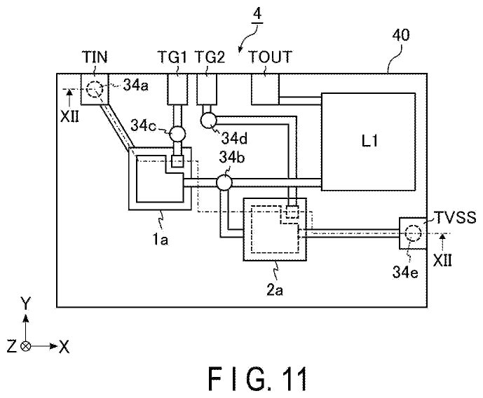

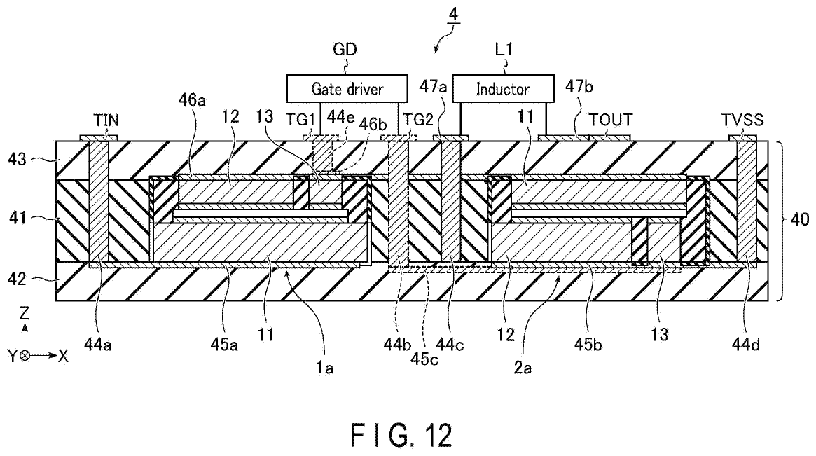

Next, a planar layout and a cross-sectional structure of the power conversion device of the fourth embodiment are described. FIG. 11 is a top view of the power conversion device of the fourth embodiment. FIG. 12 is a cross-sectional view of the power conversion device taken along line X-X shown in FIG. 11. The cross-sectional view shown in FIG. 12 shows not only the structure seen on the cross section but also the structures that can be seen through the cross section, such as through holes and interconnect layers. The power conversion device 4 includes a structure in which the semiconductor devices 1a and 2a are embedded in the printed wiring board 40. The printed wiring board 40 is a multilayered wiring board including a plurality of interconnect layers, a plurality of insulating plates (or insulating layers), and a core member.

As shown in FIGS. 11 and 12, the power conversion device 4 includes a plurality of semiconductor devices 1a and 2a, core members (or insulating members) 41, insulating plates (or insulating layers) 42 and 43, through holes 44a, 44b, 44c, 44d, and 44e, interconnect layers 45a, 45b, 45c, 46a, 46b, 47a, and 47b, an input terminal TIN, an output terminal TOUT, gate terminals TG1 and TG2, a ground terminal TVSS (namely a voltage VSS node), an inductor L1, and capacitors C1 and C2. The capacitors C1 and C2 are provided at positions not shown in the drawings. Each of the insulating plates 42 and 43 has, for example, a shape of a sheet and is made of an insulating material obtained by impregnating a thermoset resin in carbon fibers.

As shown in FIG. 12, the semiconductor device 1a is provided between the insulating plate 42 and the insulating plate 43 with respect to the Z direction and between the core members 41 with respect to the X direction and the Y direction. Similarly, the semiconductor device 2a is provided between the insulating plate 42 and the insulating plate 43 with respect to the Z direction, and provided between the core members 41 with respect to the X direction and the Y direction.

In other words, the semiconductor devices 1a and 2a are provided separately from each other on the insulating plate 42. The insulating plate 43 is provided on the semiconductor devices 1a and 2a. The core members 41 are provided on the side surfaces of the semiconductor devices 1a and 2a. In other words, the core members 41 are provided so as to cover the side surfaces of the semiconductor device 1a. Similarly, the core member 41 are provided so as to cover the side surfaces of the semiconductor device 2a.

The input terminal TIN, the output terminal TOUT, the gate terminals TG1 and TG2, and the ground terminal TVSS are provided on the insulating plate 43.

The through holes 44a, 44b, 44c, and 44d are provided in the insulating plate 43 and the core member 41. Each of the through holes 44a, 44b, 44c, and 44d extends in the insulating plate 43 and the core member 41 in the Z direction. The through hole 44e is provided in the insulating plate 43. The through hole 44e extends in the insulating plate 43 in the Z direction.

An interconnect layer 45a is provided between the drain electrode plate 11 of the semiconductor device 1a and the insulating plate 42. The interconnect layer 45a diagonally extends with respect to the X direction and the Y direction. An interconnect layer 46a is provided between the source electrode plate 12 of the semiconductor device 1a and the insulating plate 43. The interconnect layer 46a extends in the X direction. The interconnect layer 46b is provided between the gate electrode plate 13 of the semiconductor device 1a and the insulating plate 43. The interconnect layer 46b extends in the Y direction.

An interconnect layer 45b is provided between the source electrode plate 12 of the semiconductor device 2a and the insulating plate 42. The interconnect layer 45b extends in the X direction. The interconnect layer 45c is provided between the gate electrode plate 13 of the semiconductor device 2a and the insulating plate 42. The interconnect layer 45c extends in the X direction and the Y direction. The interconnect layer 46a is provided between the drain electrode plate 11 of the semiconductor device 2a and the insulating plate 43. Interconnect layers 47a and 47b are provided on the insulating plate 43. The interconnect layers 47a and 47b extend in the X direction.

The input terminal TIN is coupled to the through hole 44a. The through hole 44a is coupled to the interconnect layer 45a. The interconnect layer 45a is further coupled to the drain electrode plate 11 of the semiconductor device 1a.

The source electrode plate 12 of the semiconductor device 1a is coupled to the interconnect layer 46a. The interconnect layer 46a is coupled to the through hole 44c. The through hole 44c is coupled to the first end of the inductor L1 via the interconnect layer 47a. The interconnect layer 46a is further coupled to the drain electrode plate 11 of the semiconductor device 2a. The second end of the inductor L1 is coupled to the output terminal TOUT via the interconnect layer 47b.

The source electrode plate 12 of the semiconductor device 1b is coupled to the interconnect layer 45a. The interconnect layer 45a is coupled to the through hole 44d. The through hole 44d is coupled to the terminal TVSS.

The gate electrode plate 13 of the semiconductor device 1a is coupled to the through hole 44e via the interconnect layer 46b. The through hole 44e is coupled to the gate terminal TG1. The gate electrode plate 13 of the semiconductor device 2a is coupled to the through hole 44b via the interconnect layer 45c. The through hole 44b is coupled to the gate terminal TG2. A gate driver GD is coupled to the gate terminals TG1 and TG2.

Hereinafter, major advantageous effects of the fourth embodiment are explained.

According to the foregoing fourth embodiment, it is possible to easily embed the semiconductor devices 1a and 1b in the printed board, and to form a power conversion device, such as a DC-DC converter, with a small area. The other advantages are the same as those of the first embodiment.

### 5. Fifth Embodiment

A power conversion device according to the fifth embodiment is described. In the fifth embodiment, a power conversion device comprising a plurality of surface mount semiconductor devices, for example quad flat non-leaded package (QFN) semiconductor devices, is described. The explanation of the fifth embodiment will focus mainly on the points that differ from the third embodiment.

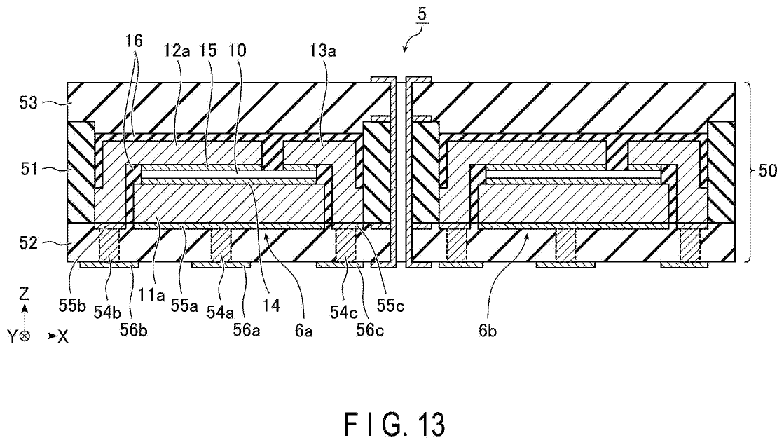

Next, a cross-sectional structure of the power conversion device of the fifth embodiment are described. FIG. 13 is a cross-sectional view of a power conversion device according to the fifth embodiment. The cross-sectional view shown in FIG. 13 shows not only the structure seen on the cross section but also the structures that can be seen through the cross section, such as through holes and interconnect layers. The power conversion device 5 includes a structure in which the semiconductor devices 6a and 6b are embedded in the printed wiring board 50. The printed wiring board 50 is a single-surface wiring board including single-surface interconnect layers, a plurality of insulating plates (or insulating layers), and a core member.

As shown in FIG. 13, the power conversion device 5 includes a plurality of semiconductor devices 6a and 6b, core members (or insulating members) 51, insulating plates (or insulating layers) 52 and 53, through holes 54a, 54b, and 54c, interconnect layers 55a, 55b, and 55c, a drain terminal 56a, a source terminal 56b, and a gate terminal 56c. Herein, the descriptions of the passive components, such as inductors and capacitors, are omitted. Each of the insulating plates 52 and 53 has, for example, a shape of a sheet and is made of an insulating material obtained by impregnating a thermoset resin in carbon fibers.

Each of the semiconductor devices 6a and 6b includes a semiconductor chip 10, a drain electrode layer 11a, a source electrode layer 12a, a gate electrode layer 13a, conductive layers 14 and 15, and mold layers 16, as shown in FIG. 13.

The semiconductor chip 10 includes a MOSFET, for example. The semiconductor chip 10 has a first surface orthogonal to the Z direction and a second surface facing the first surface. The first surface is the lower surface of the semiconductor chip 10 shown in FIG. 13, and the second surface is the upper surface of the semiconductor chip 10 shown in FIG. 13. The semiconductor chip 10 has a drain region on the first surface and a source region and a gate region on the second surface.

The semiconductor chip 10 is provided between the drain electrode layer 11a and the source electrode and gate electrode layers 12a and 13a. In other words, the drain electrode layer 11a is provided below the drain region of the semiconductor chip 10. The source electrode layer 12a is provided on the source region of the semiconductor chip 10. Furthermore, the gate electrode layer 13a is provided on the gate region of the semiconductor chip 10.

The drain electrode layer 11a has a thin-plate shape, and includes a lead frame, for example. The thickness of the drain electrode layer 11a is, for example, 50 μm or greater, or 150 μm or greater and 300 μm or less. Similar to the drain electrode layer 11a, the source electrode layer 12a has a thin-plate shape, and includes a lead frame, for example. The thickness of the source electrode layer 12a is, for example, 50 μm or greater, or 150 μm or greater and 300 μm or less. The gate electrode layer 13a has a thin-plate shape, and includes a lead frame, for example. The thickness of the gate electrode layer 13a is, for example, 50 μm or greater, or 150 μm or greater and 300 μm or less. The drain electrode layer 11a, the source electrode layer 12a, and the gate electrode layer 13a contain Cu, for example.

As shown in FIG. 13, the semiconductor device 6a is provided between the insulating plate 52 and the insulating plate 53 with respect to the z direction and provided between the core members 51 with respect to the X direction and the Y direction. Similarly, the semiconductor device 6b is provided between the insulating plate 52 and the insulating plate 53 with respect to the Z direction, and provided between the core members 51 with respect to the X direction and the Y direction.

In other words, the semiconductor devices 6a and 6b are provided separately from each other on the insulating plate 52. The insulating plate 53 is provided on the semiconductor devices 6a and 6b. The core members 51 are provided on the side surfaces of the semiconductor devices 6a and 6b. In other words, the core members 51 are provided so as to cover the side surfaces of the semiconductor device 6a. Similarly, the core members 51 is provided so as to cover the side surfaces of the semiconductor device 6b.

A drain terminal 56a, a source terminal 56b, and a gate terminal 56c are provided on the lower surface of the insulating plate 52.

The through holes 54a, 54b, and 54c are provided in the insulating plate 52. Through holes 54a, 54b, and 54c extend in the Z direction in the insulating plate 52.

An interconnect layer 55a is provided between the drain electrode layer 11a of the semiconductor device 6a and the insulating plate 52. The interconnect layer 55a extends in the X direction or the Y direction. The source electrode layer 12a of the semiconductor device 6a is drawn out to the lower surface of the semiconductor device 6a by the conductive layer. The interconnect layer 55b is provided between the conductive layer of the source electrode layer 12a and the insulating plate 52. The interconnect layer 55b extends in the X direction or the Y direction. The gate electrode layer 13a of the semiconductor device 6a is drawn out to the lower surface of the semiconductor device 6a by the conductive layer. The interconnect layer 55c is provided between the conductive layer of gate source electrode layer 13a and the insulating plate 52. The interconnect layer 55c extends in the X direction or the Y direction.

The drain electrode layer 11a of the semiconductor device 6a is coupled to the interconnect layer 55a. The interconnect layer 55a is coupled to the drain terminal 56a via the through hole 54a. The source electrode layer 12a of the semiconductor device 6a is coupled to the interconnect layer 55b via the conductive layer. The interconnect layer 55b is coupled to the source terminal 56b via the through hole 54b. The gate electrode layer 13a of the semiconductor device 6a is further coupled to the interconnect layer 55c via the conductive layer. The interconnect layer 55c is coupled to the gate terminal 56c via the through hole 54c.

Since the structure that includes the members provided on the first surface, the second surface, and the side surfaces of the semiconductor device 6b is the same as that of the semiconductor device 6a, the description thereof is omitted.

According to the structure of the foregoing fifth embodiment, it is possible to reduce the number of interconnect layers to be used by embedding the semiconductor devices 1a and 2a in a printed board and drawing out the interconnects of a source, a drain, and a gate to a single interconnect layer. In other words, it is possible to embed the semiconductor devices 1a and 2a in a single-surface printed board. The other advantages are the same as those of the first embodiment.

### 6. Others

In the foregoing embodiments, the examples are given in which a DC-DC converter is a power conversion device; however, the power conversion device is not limited to a DC-DC converter, and the embodiments can be applied to other types of power conversion devices, such as an inverter, etc.

While certain embodiments have been described, these embodiments have been presented by way of example only, and are not intended to limit the scope of the inventions. Indeed, the novel embodiments described herein may be implemented in various other forms, and various omissions, replacements, and changes can be made without departing from the gist of the invention. The accompanying claims and their equivalents are intended to cover such forms or modifications as would fall within the scope and spirit of the inventions.

What is claimed is:

1. A semiconductor device comprising:
a semiconductor chip having a drain region on a first surface, and a source region and a gate region on a second surface facing the first surface;
a drain electrode provided in the drain region;
a source electrode provided in the source region;
a gate electrode provided in the gate region;
mold layers provided on side surfaces of the semiconductor chip, the source electrode, and the gate electrode;
first coating films provided on a lower surface and side surfaces of the drain electrode, an upper surface of the source electrode, and an upper surface of the gate electrode; and
second coating films provided on an upper surface and side surfaces of the mold layers.

2. The semiconductor device according to claim 1, wherein
each of the drain electrode, the source electrode, and the gate electrode contains Cu and has a thickness of 50 μm or greater.

3. The semiconductor device according to claim 1, wherein
each of the drain electrode, the source electrode, and the gate electrode contains Cu and has a thickness of 150 μm or greater and 300 μm or less.

4. The semiconductor device according to claim 1 further comprising a first electrode layer provided between the drain region of the semiconductor chip and the drain electrode, wherein
the first electrode layer includes one of a stacked structure of Al, Ni, and Au, a stacked structure of Al, Ni, Pd, and Au, a stacked structure of Al and Cu, or a single-layer structure of Cu.

5. The semiconductor device according to claim 4 further comprising a first conductive layer provided between the first electrode layer and the drain electrode, wherein
the first conductive layer contains one of Ag, Cu, CuSn, AgSn, AuSn, or PbSn.

6. The semiconductor device according to claim 1 further comprising:
a second electrode layer provided between the source region of the semiconductor chip and the source electrode; and
a third electrode layer provided between the gate region of the semiconductor chip and the gate electrode, wherein
each of the second electrode layer and the third electrode layer includes one of a stacked structure of Al, Ni, and Au, a stacked structure of Al, Ni, Pd, and Au, a stacked structure of Al and Cu, or a single-layer structure of Cu.

7. The semiconductor device according to claim 6 further comprising:
a second conductive layer provided between the second electrode layer and the source electrode; and
a third conductive layer provided between the third electrode layer and the gate electrode, wherein
each of the second conductive layer and the third conductive layer contains at least one of Ag, Cu, CuSn, AgSn, AuSn, or PbSn.

8. The semiconductor device according to claim 1, wherein
the first coating film contains benzotriazole (BTA).

9. The semiconductor device according to claim 1, wherein
the first coating film includes one of a film containing Sn, a film containing Ni and Au, or a film containing Ni, Pd, and Au.

10. The semiconductor device according to claim 1, wherein
the semiconductor device has a stacked structure in which the drain electrode, the semiconductor chip, and the source electrode are stacked in this order, and
a thickness of the stacking structure is 500 μm or less.

11. A power conversion device comprising:
a first insulating plate;
a second insulating plate provided above the first insulating plate; and
a first semiconductor device provided between the first insulating plate and the second insulating plate, wherein
the first semiconductor device comprises:
a first semiconductor chip having a first drain region on a first surface, and a first source region and a first gate region on a second surface facing the first surface;
a first drain electrode provided on the first drain region;
a first source electrode provided on the first source region; and
a first gate electrode provided on the first gate region.

12. The power conversion device according to claim 11, further comprising a second semiconductor device provided between the first insulating plate and the second insulating plate, wherein
the second semiconductor device comprises:
a second semiconductor chip having a second drain region on a first surface, and a second source region and a second gate region on a second surface facing the first surface;
a second drain electrode provided on the second drain region;
a second source electrode provided on the second source region; and
a second gate electrode provided on the second gate region.

13. The power conversion device according to claim 11, further comprising an insulating member provided between the first insulating plate and the second insulating plate, with the first semiconductor device being interposed therebetween.

14. The power conversion device according to claim 12, wherein
the first semiconductor device includes:
first mold layers provided on side surfaces of the first semiconductor chip, the first source electrode, and the first gate electrode;
first coating films provided on a lower surface and side surfaces of the first drain electrode, an upper surface of the first source electrode, and an upper surface of the first gate electrode; and
second coating films provided on an upper surface and side surfaces of the first mold layers, and
the second semiconductor device includes:
second mold layers provided on side surfaces of the second semiconductor chip, the second source electrode, and the second gate electrode;
third coating films provided on a lower surface and side surfaces of the second drain electrode, an upper surface of the second source electrode, and an upper surface of the second gate electrode; and
fourth coating films provided on an upper surface and side surfaces of the second mold layers.

15. The power conversion device according to claim 11, wherein
the first semiconductor device includes a first electrode layer provided between the first drain region of the first semiconductor chip and the first drain electrode, wherein
the first electrode layer includes one of a stacked structure of Al, Ni, and Au, a stacked structure of Al, Ni, Pd, and Au, a stacked structure of Al and Cu, or a single-layer structure of Cu.

16. The power conversion device according to claim 15, wherein
the first semiconductor device includes a first conductive layer provided between the first electrode layer and the first drain electrode, and
the first conductive layer contains at least one of Ag, Cu, CuSn, AgSn, AuSn, or PbSn.

17. The power conversion device according to claim 11, wherein
the first semiconductor device includes a second electrode layer provided between the first source region of the first semiconductor chip and the source electrode, and a third electrode layer provided between the first gate region of the first semiconductor chip and the first gate electrode; and
each of the second electrode layer and the third electrode layer includes one of a stacked structure of Al, Ni, and Au, a stacked structure of Al, Ni, Pd, and Au, a stacked structure of Al and Cu, or a single-layer structure of Cu.

18. The power conversion device according to claim 17, wherein
the first semiconductor device includes a second conductive layer provided between the second electrode layer and the source electrode, and a third conductive layer provided between the third electrode layer and the first gate electrode, and
each of the second conductive layer and the third conductive layer contains at least one of Ag, Cu, CuSn, AgSn, AuSn, or PbSn.

19. The power conversion device according to claim 14, wherein
the first and third coating films contain benzotriazole (BTA).

20. The power conversion device according to claim 14, wherein
each of the first and third coating films is one of a film containing Sn, a film containing Ni and Au, or a film containing Ni, Pd, and Au.
